(19) United States
(12) Patent Application Publication
(10) Pub. No.: US 2017/0035002 A1
(43) Pub. Date: Feb. 9, 2017

(54) APPARATUS FOR OPTIMIZING AND ENHANCING PLANT GROWTH, DEVELOPMENT AND PERFORMANCE

(71) Applicants: Craig Ellins, LAS VEGAS, NV (US); Todd Denkin, Henderson, NV (US); Wayne Love, HENDERSON, NV (US); Ulrich Reimann-Philipp, LAS VEGAS, NV (US); Andrea Small-Howard, LOS ANGELES, CA (US); Lucas Marin, Las Vegas, NV (US); Jorge Velez, San Juan, PR (US); Cesar Cordero Kruger, Santurce, PR (US)

(72) Inventors: Craig Ellins, LAS VEGAS, NV (US); Todd Denkin, Henderson, NV (US); Wayne Love, HENDERSON, NV (US); Ulrich Reimann-Philipp, LAS VEGAS, NV (US); Andrea Small-Howard, LOS ANGELES, CA (US); Lucas Marin, Las Vegas, NV (US); Jorge Velez, San Juan, PR (US); Cesar Cordero Kruger, Santurce, PR (US)

(21) Appl. No.: 14/821,742

(22) Filed: Aug. 9, 2015

(51) Int. Cl. A01G 9/24; G05B 15/02; G06F 17/50; A01G 31/02; A01G 7/04

(52) U.S. Cl. CPC A01G 9/247; A01G 31/02; A01G 7/045; G06F 17/5009; G05B 15/02

(57) ABSTRACT

An apparatus to optimize and enhance plant growth, development and performance at any stage of its development including sowing, growth, flowering, fruit formation or during many processes associated with the handling of the culture through an automated, enclosed and controlled environment system.

### CROSS REFERENCES TO RELATED APPLICATIONS

Not applicable. The present application is an original and first-filed United States Utility Patent Application.

### STATEMENT REGARDING FEDERALLY SPONSORED RESEARCH OR DEVELOPMENT

Not applicable.

### THE NAMES OR PARTIES TO A JOINT RESEARCH AGREEMENT

Not applicable.

### INCORPORATION BY REFERENCE OF MATERIAL SUBMITTED ON A COMPACT DISC

Not applicable.

### BACKGROUND OF THE INVENTION

1. Field of the Invention

The present invention relates generally to an apparatus to optimize and enhance plant growth, development and performance at any stage of its development including sowing, growth, flowering, fruit formation or during many processes associated with the handling of the culture through an automated, enclosed and controlled environment system.

More particularly the invention relates to an enclosed chamber with reflective interior wall elements and high efficiency LED lighting at specified wavelengths and temperature together with an integrated control system to accelerate plant growth and optimize the quality and efficacy of the plant.

The invention further relates to a nutrient delivery system to effectively and optimally provide moisture, nutrients, carbon dioxide and related growth and performance optimizing agents to the plant root structure in an automated, controlled and contained manner in order to minimize the cost of nutrients while concomitantly maximizing the plant growth and substantially eliminating plant contamination and disease when compared to conventionally grown plants.

The invention more particularly relates to a high efficiency, enclosed apparatus with integrated controls systems to provide optimal nutrient solutions to medicinal and non-medicinal plants in order to maximize their efficacy and enhance their growth, performance and development. The apparatus and system will be described in relationship to a methodology for optimizing plant growth. This is not to be understood as any limitation inasmuch as the system may be employed with a number of plant growth optimization methodologies.

2. Technical Background

Plants can only take up nutrient ions that are located in the vicinity of the root surface. In nature, positioning of the nutrient ion can occur by one or more of three processes. The root can “bump into” the ion as it grows through the soil. This mechanism is called root interception. It is generally found that perhaps one to five percent of the nutrients in plants grown in soil come from the root interception process.

The soluble fraction of nutrients present in soil solution (water) and not held on the soil fractions flow to the root as water is taken up. This process is called mass flow. Nutrients such as nitrate-N, calcium and sulfur are normally supplied by mass flow.

Nutrients such as phosphorus and potassium adsorb strongly to soils and are only present in small quantities in the soil solution. These nutrients move to the root by diffusion. As uptake of these nutrients occurs at the root, the concentration in the soil solution in close proximity to the root decreases. This creates a gradient for the nutrient to diffuse through the soil solution from a zone of high concentration to the depleted solution adjacent to the root. Diffusion is responsible for the majority of the P, K and Zn moving to the root for uptake.

However, as can be appreciated from the above nutrient positioning mechanisms, uptake can be a fairly random event and result in non-optimal growth and development for a plant. The actual nutrient uptake process may cause a plant not to grow in an optimal manner.

Uptake of nutrients by a plant root is an active process. As water is taken up to support transpiration, nutrients may be moved to the root surface through mass flow. At this point, an active uptake process that requires energy is used to move the nutrients into the root cells and translocate them to the vascular system for transport to the growing tissues.

Specific protein carrier structures are used to bind nutrient ions and transport them across the root cell membrane. This active uptake process is also selective. The root cells discriminate and only expend energy to take up those nutrients the plant needs. Thus, nutrient uptake is not proportional to the ratios of nutrients in the soil solution. Ions in large supply in the soil solution, such as calcium and sulfur, can accumulate near the root. In perennial plants this can actually result in visible quantities of calcium carbonate and calcium sulfate precipitating and coating old roots.

One important implication of the plants ability to pick and choose nutrients from the soil solution is the relative unimportance of the ratio of nutrients in the soil solution. As long as a given nutrient is supplied to the root surface at a concentration high enough to meet the demands of nutrient uptake, the demands of growth and development will normally be met. For example, the ratio of calcium and magnesium on the soil cation exchange sites and in soil solution has little effect on the ratio of these nutrients in the plant. The plant selects the ions it needs, allowing the others to accumulate in the soil solution at the root surface. Altering the soil to supply adequate amounts, the concept of critical concentrations, has generally proven more cost effective than altering soils to provide ratios of nutrients equivalent to the ratios at which the nutrients are found in the plants.

Thus, it would be desirable and advantageous to be able to supply a plant with the nutrients it needs in the amounts that it requires them, thus minimizing waste of nutrient supplies and optimizing a plant's ion selection action. This would also minimize excessive accumulation of unused nutrient salts at the root surface. It is also important to note that the normal patterns of nutrient uptake parallel plant vegetative growth in many ways. Most plants, and particularly crops that are to provide food or for medical usage take up the majority of the nutrients during the periods of vegetative growth and translocate stored nutrients to developing flowers, seeds and fruit during reproductive growth.

The amount and composition of the nutrient mix that the plant needs for optimal growth change during its development. Nutrient uptake increases rapidly from the early stages of growth to just prior to generation of reproductive mechanisms, and then stays at high levels until after pollination. Thus, it would be highly advantageous to be able to regulate the amount of nutrients available during respective growth phases and vary them according to the relative needs at any given time, thereby further minimizing nutrient waste.

3. Ecological Background

As the population on Earth increases and the improper development and usage of natural resources continues, arable lands disappear and vegetation on the earth's surface decreases at rapid rates. As a result, the problem of food shortage is getting more serious, the ability of converting carbon dioxide (CO₂) into oxygen (O₂) in the atmospheric environment by photosynthesis is reduced substantially, and the problem of global warming caused by greenhouse effect has gone from bad to worse. The need to maximize the use of arable lands for sustainable agriculture is sometimes outweighed by the desire to maximize the profitability of each arable acre with high-dollar yield crops that may have little or no nutritional value and may have deleterious health consequences, such as tobacco production.

Abnormal climatic changes are caused by the continuously increased temperatures on the earth's surface because of greenhouse effect. The climatic changes are the cause of: a) the yearly reduction of global rainfall and the reduction of accumulated snow on high mountains both of which result in the decline of water sources and droughts; b) the rise of sea level which results in flooding and the reduction of land area; the excessive rainfall in regional areas which results in the changes of growing cycles as well as distributions of plants and crops. As a result, plants and crops are seriously affected by floods, droughts, windstorms, plant diseases as well as insect pests. Thus it is imperative that water usage be optimized in plant cultivation and that methodologies be developed that permit water absorption and nutrient delivery to maximize a plant's growth and enhance its productivity.

Developing large areas of arable lands, improving cultivation techniques and adapting crop cultivars through selective breeding are time-consuming and alone cannot cope with the problems of food shortage and decline of arable land caused by droughts, floods, plant diseases, insect pests and chilling injury that are in part caused by climate change. Current agricultural practices including large scale genetic plant programs often create new or competing problems and issues. Moreover, improvement on the breeds of plants and crops is time-consuming. Furthermore, because arable lands on the Earth are limited, expanding the scale of cultivation is not feasible even if new breeds of plants and crops are developed successfully. Therefore, food shortage is still a problem which remains unsolved.

Many non-edible plants that have useful properties often need to compete for arable land with food crops. Medicinal plants have been cultivated and processed by individuals, families and communities from the beginning of humankind. Preparation methods for a myriad of medicinal use plants have been handed down, modified or lost over time. For many years, the cultivation, preparation, and use of certain medicinal plants was limited by cultural or religious concerns, or legally prohibited by governments.

In recent years, government restrictions on the cultivation, preparation, and/or use of certain medicinal plants have been revised or relaxed. As such, needs have arisen for controlled and optimized facilities in which medicinal plants can be cultivated and prepared for therapeutic or recreational uses. Ideally, the growth of these medicinal plants would take place under controlled and optimized conditions to create botanical materials, for distribution specifically to persons who are legally authorized or permitted to do so in certain countries, states or regions. In some situations, the quantity of a medicinal plant possessed by an individual is regulated.

Aeroponics, which is also called “air culture” or “soilless culture”, is presently the most modern and technologically evolved cultivation system for plant production. In aeroponics, plants are grown in the absence of any substrate. The nutrient solution is sprayed directly on the plant roots, which grow suspended in the air within closed trays or vessels. The ideal conditions of absorption of carbon dioxide, water and nutrient ions by the plants' root system result in the more rapid growth and maturation rates of the plants, the bigger density of planting and the easier control of pests and diseases. Also, plant cultivation can be repeated year-round without interruption.

Air culture systems available today around the world for research or for productions purposes, are closed cultivations systems, usually consisting of:
A central control unit (head tank), or peripheral units for managing parts of the system and containers for automatic preparation of nutrient solution by mixing nutrient stock solutions with automatic adjustment of pH and conductivity values.
An automatic irrigation system for spraying or misting the nutrient solution under low of high pressure onto the plants' roots, controlling the duration and frequency of spraying with automatic regulation of the time and frequency of injection. The nutrient solution is re-circulated from the plant growing trays or vessels back to the central control unit.
Trays or vessels into which the root system develops are arranged vertically or horizontally and are made from plastic or metal materials of different types, shapes and forms. In many cases, the container in which plants are grown also contains the nutrient solution.

The aeroponic systems which have been constructed so far have several major drawback, which have prevented their widespread application. One such drawback is that there has previously been no system to adjust the temperature to the optimal level for individual plants or groups of plants within one system. The temperature is a critical factor in relation to the type of crop plant and external temperature conditions. Also containers or channels into which development of the root systems occurs are not insulated properly. Plastic or metal materials are mainly used today for channels or receptacles into which the developed root systems are confined. These do not offer insulation.

A second major drawback of the currently known aeroponic cultivation systems is that they cannot simultaneously support multiple cultures of various plants (multicrop), or cultures with different nutritional needs. Similarly, currently known aeroponic systems do not provide optimal protection from outside contaminants such as air-borne and water-borne harmful chemicals, nor from infection and infestation by pathogens and pests. They also do not maximize the wavelength spectrum and photon flux of the available light, while simultaneously employing energy efficient technology to minimize the power consumption of the light source.

Traditional aeroponic fogging/hydroponic foggers have be used for many horticultural applications including root fogging, foliar feeding, growroom & greenhouse humidity generation and even ultra low volume (ULV) pesticide application. These ultrasonic foggers assist in propagation and production and can be used to optimize the environments for plants to grow. An aeroponic fogger can operate by oscillating at a frequency of approximately 2 MHZ, which is two million vibrations per second. At this frequency, water is nebulized into a cold fog/dry fog that can support the needs of plants using an ultra low volume (ULV) of water and nutrients. An aeroponic fogger may also generate an extremely small droplet that averages only 2.5 microns which is small enough to be absorbed by roots and leaves on contact and can be effective using only an ultra low volume of liquid.

However, it has been determined that excessive fogging may have deleterious effects such as root rot. Regular fogging (5 μM droplets) is the likely cause of lower stem rot in certain aeroponic applications and by itself not sufficient to deliver all nutrients. An aspect of the invention is the unexpected discovery that intermittent spraying of the roots with a coarser mist (20-50 μM droplets) provides much better results. The fog is not essential for growing the plant.

Fog can still be useful for “shocking” roots in order to elicit biochemical responses, to adjust humidity in the root zone, and to deliver oxidizers or other chemicals to sanitize the roots. However, plants that are exposed to coarser mist do not develop typical “fog roots” so the effect of the fogging for stressing the plants might be limited. Also, fast, temporary effects would require a method to deliver the solution from a different tank than the main tank or drain tank.

It has also been discovered, and is part of this invention, that fog should only be applied as an insurance in case the roots dry out or to deliver sudden stress. This requires a separate tank. Fog may continue to be used, but only at proper intervals as to not “over-fog” the stem and roots of the plant and cause rot.

Current aeroponic systems also do not employ “just-in-time” fogging or misting to provide the roots with just enough nutrient solution in a fine mist to provide the necessary nutrients for optimal growth while also providing growth stimulating oxygen at the optimal levels to maximize the plant's root elongation.

In addition, current aeroponic systems to not employ control feedback loops to simultaneously provide data on current crops to maximize yields and generate long term data to apply to analytical models that permit future plantings and harvests to be optimized both as to yield, quality and timing. The data and analytics permit successive crops to be planted and harvested to provide a substantially continuous yield with optimal harvest times in close proximity to one another while simultaneously not overstocking the market with product and causing an oversupply at a particular time.

Accordingly, the present invention seeks to address one or more of the above-described situations and needs.

### SUMMARY OF THE INVENTION

It is therefore one object of the present invention to provide a method of enhancing the metabolic and growth processes and functions of plants by optimizing the growing conditions of these plants.

It is still another object of the present invention to provide a method of enhancing the metabolic functions and the growing conditions of plants by optimizing the nutrient absorption and providing variable nutrient supplies based upon developmental stage, physiological responses, absorption rates and other variables for which the invention is able to obtain data to be used to model future plant growth enhancement.

It is yet another aspect of the invention to provide an apparatus for growing medicinal and recreational plants comprising a grow environment enclosure, a support structure positioned in the grow environment enclosure and adapted to support growing medicinal or recreational plants, an nutrient delivery system coupled to the support structure and adapted to deliver micro-droplets of nutrient-laden mist or dry fog to the medicinal or recreational plants, a variable intensity and wavelength light system positioned in the grow environment enclosure and adapted for growing medicinal or recreational plants and means for real time monitoring, managing and controlling the operation of the system based upon real-time sensed parameters (illustratively temperature, nutrient levels, lighting, mist schedules, CO₂, pH levels and other growth and plant health related items).

Another aspect of the invention is where the monitoring and adjustment means further comprises a telecommunication system coupled to the grow environment enclosure, where the telecommunication system is configured to allow remote monitoring and control of the grow environment system, including alerts for each of the real-time sensed parameters.

A still further aspect of the invention is where the telecommunication system comprises a video camera adapted to transmit images from within the grow environment enclosure.

A further aspect of the invention is a climate control system adapted to control the environment within the grow environment enclosure.

A yet further aspect of the invention is a water circulation and storage system adapted to couple to the nutrient delivery system.

Another aspect of the invention is a CO₂ monitoring, controlling and enrichment system.

A further aspect of the invention is an apparatus for growing plants that comprises a grow environment enclosure, where the grow environment enclosure may alternatively be configured to be portable where a system may be moved from one place to another.

A still further aspect of the invention is providing a climate control system for the grow environment enclosure.

It is yet a further aspect of the invention to provide light beams produced by the light emitting diodes with certain wavelengths to enhance the photosynthesis of the plants in order to speed up the growth rates and production quantities of plants.

A further aspect of the invention is to provide for the preparation of some or all of the nutrient solutions according to the needs of the growing crops in a fully automatically controlled system.

It is still another aspect to the invention to provide for either single or multiple crop growth environments wherein the one or more crop tanks are capable of providing the nutrient solutions' to separate reservoirs or containers for each crop.

It is yet a further aspect of the invention that the nutrient solution may be configured generally for a plurality of crops and then altered for the individual crop prior to transfer from a main container to an individual crop tank wherein the resultant nutrient combination is nebulized or otherwise delivered via microdroplets to provide a nutrient mist directly to the exposed root portions of the plants.

It is a further aspect of the invention to provide extruded growing containers or root reservoirs, which can be made of various shapes or forms and can be used for flat or vertical cultivation, in communication with the nutrient misting inlet ports, into which the root system of the plants is provided with nutrient and in which it develops.

It is still a further aspect of the invention to provide for a thermally insulated space for root development to protect the root environment from temperature disturbances and make it alternatively suitable for operation in either an indoor or outdoor environment, depending on the external climate conditions.

It is yet another aspect of the invention to provide an automatic root misting irrigation system whereby the nutrient solution is delivered under high or low pressure by one or more pumps, transport pipes, misters and sprayers under pressure (high or low) directly to the root portions in the root development containers, with either automatic or manual setting of time and frequency of mist provision and the ability to vary each parameter automatically in relation to collected data points or based upon other criteria.

It is a further element of the invention to provide a closed circuit supply system that recirculates the nutrient solution from the growing channels or containers back to the nutrient solution tanks via reclamation tanks and return pumps or by natural flow and to include, advantageously, a tank cleansing system for the nutrient solution to prevent any plant related contamination, disease or other plant health diminishing factors.

It is a further feature of the present invention to provide an integrated plant illumination system that can monitor and detect environment and plant growth parameters and adjust illumination based upon the parameters and according to growth models detailed by the grower. The plant illumination system may also be capable of adjusting light according to a real-time parameter to promote and enhance plant growth and vary intensity, lighting periods and light temperature pursuant to user defined variables and parameters. The invention further may provide for a processor control module includes a processor unit and a storage unit for storing a database of plant growing environment parameters including but not limited to temperature, nutrient levels, lighting, misting schedules, CO₂, pH levels and other growth and plant health related items.

The above and other objects, features and advantages of this invention will be better understood when taken in connection with the following description which is given as exemplary and not limitative.

### BRIEF DESCRIPTION OF THE DRAWINGS

FIG. 1 is a diagrammatic representation of an example of an assembled configuration of a plant growth environment system and methodology in accordance with an embodiment of the invention.

FIG. 2 is a diagrammatic representation of a top view of an example of an assembled configuration of a plant growth environment system in accordance with an embodiment of the invention.

FIG. 3 is an example of a front view an interior configuration of a plant growth environment system (with the front panels removed) in accordance with an embodiment of the invention.

FIG. 3A is an example of a rear view of an interior configuration of a plant growth environment system (with the rear panels removed) in accordance with an embodiment of the invention.

FIG. 3B is an exploded view of a cooling assembly for a configuration of a plant growth environment in accordance with an embodiment of the invention.

FIG. 3C is an exploded view of an evaporator assembly for a configuration of a plant growth environment in accordance with an embodiment of the invention.

FIG. 4 is a diagrammatic representation of a side view of an example of an assembled configuration of a plant growth environment system in accordance with an embodiment of the invention.

FIG. 5 is diagrammatic representation of a side view of an example of an assembled configuration of a plumbing system for a plant growth environment system in accordance with an embodiment of the invention.

FIG. 6 is a diagrammatic representation, in exploded form, of an example of a root box assembly of a plant growth environment system in accordance with an embodiment of the invention.

FIG. 7 is a diagrammatic representation, in assembled form, of an example of a nutrient delivery assembly of a plant growth environment system in accordance with an embodiment of the invention.

FIG. 8 is a diagrammatic representation, in exploded form, of an example of a nutrient delivery assembly of a plant growth environment system in accordance with an embodiment of the invention.

FIG. 9A is a diagrammatic representation of an example of a secure remote monitoring nutrient delivery system for a plant growth environment system in accordance with an embodiment of the invention.

FIG. 9B is a diagrammatic representation of an example of a secure remote control nutrient delivery system for a plant growth environment system in accordance with an embodiment of the invention.

FIG. 10 is a block diagram of an example of a control and nutrient delivery system for a plant growth environment system in accordance with an embodiment of the invention.

FIG. 11 is a block diagram of an example of a control and nutrient delivery system in conjunction with Internet capability in accordance with an embodiment of the invention.

### DETAILED DESCRIPTION OF AN EMBODIMENT OF THE INVENTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In a preferred embodiment there are a number of major subsystems to the self-contained plant growth environment system in accordance with the invention.

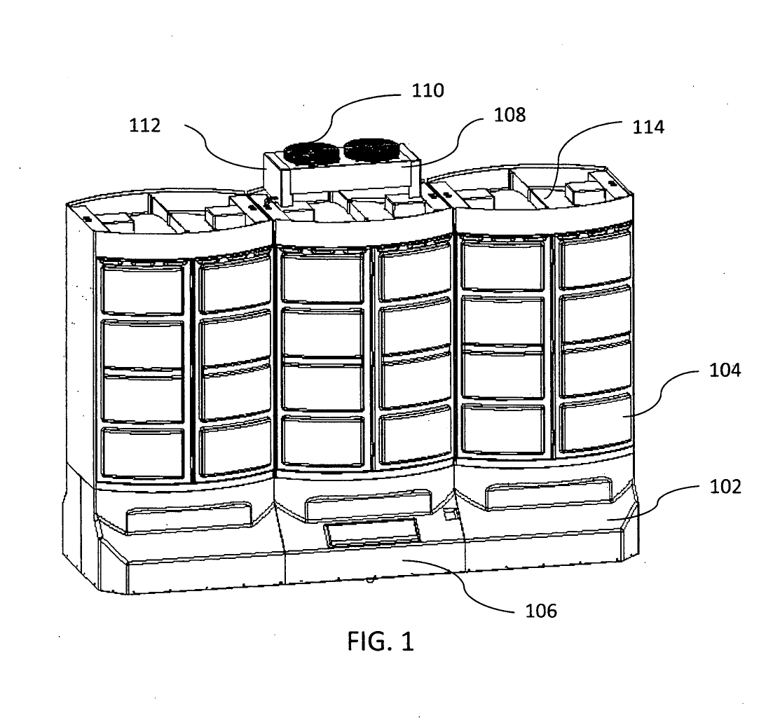

Referring to FIG. 1, there is shown a diagrammatic representation of an example unassembled configuration of plant growth delivery system 100 in accordance with one embodiment of the invention. In the particular delivery system 100, a number of the operational elements of the system such as cooling system 200 and evaporation system 300 are is covered by protective covers 102 in order to maintain the self-contained aspect of plant growth delivery system 100.

Additional protective door covers 104 are advantageously provided to further enclose the plant growth delivery system 100 in the area where the plants (not shown) are generally maintained and to further serve, on the interior surfaces thereof, as reflected internal elements for a system of light emitting diodes 400 in accordance with and embodiment of the invention.

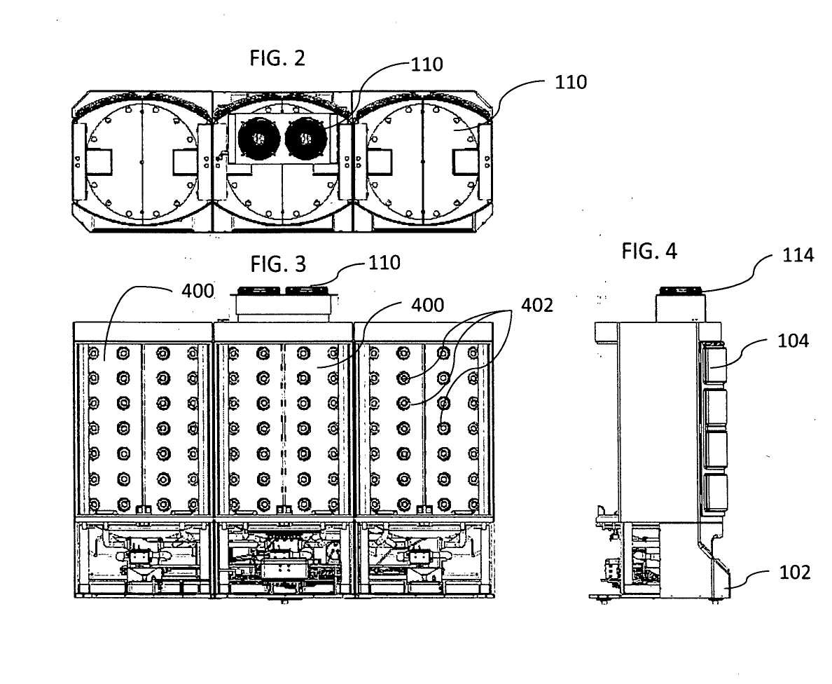

Referring to FIGS. 1-3, a nutrient coverlid 106 is removably deployed above the nutrient dispensing trays (not shown) that are provided within the plant growth delivery system 100. Air conditioning condensing unit 108 is illustratively deployed above the plant growth delivery system 100 and has disposed therein one or more condenser fans 110 and has associated there with one or more return here ducts 112 to provide the air delivery and return system for the plant growth delivery system 100. Upper ceiling covers 114 are dispose over each of the individual units of the plant growth delivery system 100 in order to provide a fully enclosed environment for the plants that are to be grown within the plant growth delivery system 100.

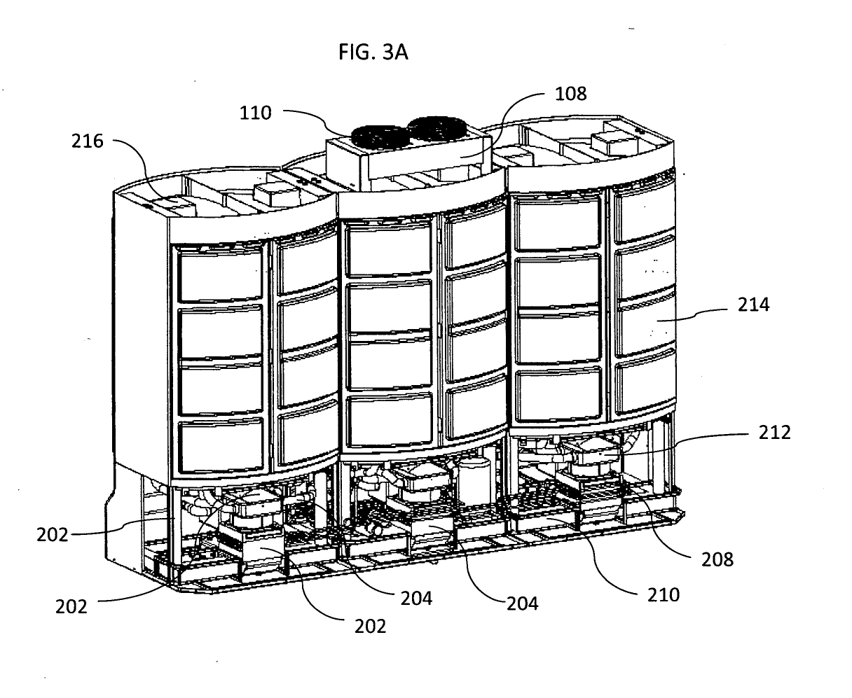

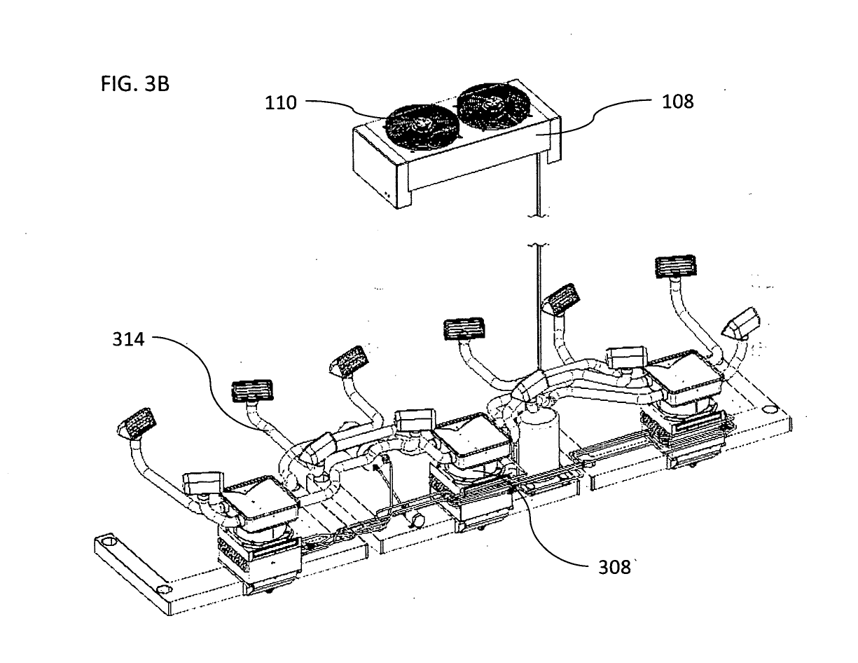

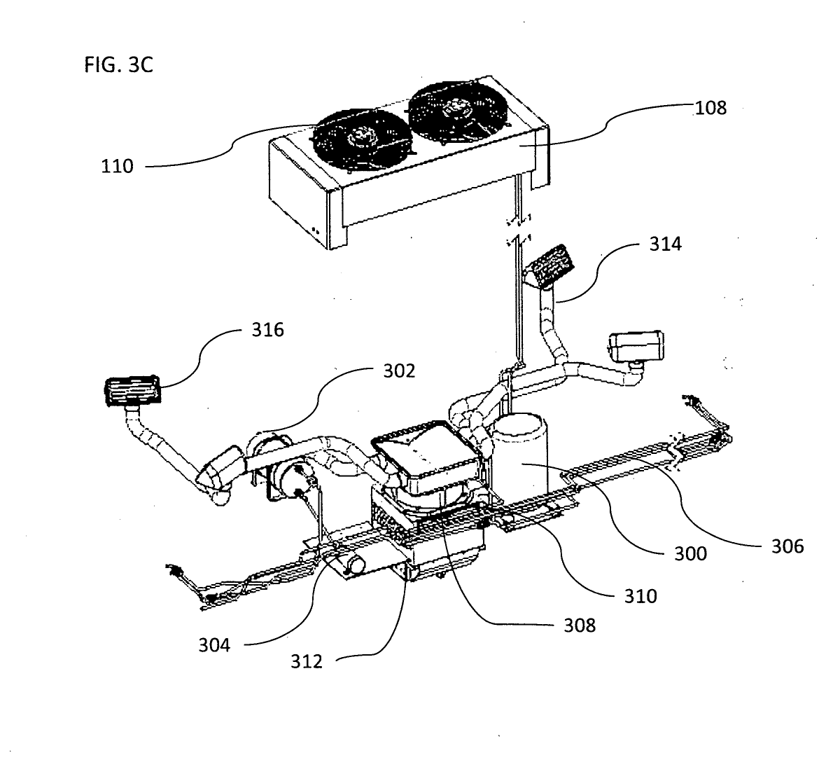

Referring to FIG. 3, there is illustrative shown the plant growth delivery system 100 with the protective doors 104 removed in order to show the system of light emitting diodes 400 advantageously deployed within each of the units of the plant growth delivery system 100. As will be further explained hereinafter, the system of light emitting diodes 400 consisting of a plurality of light emitting diodes 402, may be provided with variable wavelength diodes 402 in order to permit the plants to receive optimum light in accordance with the requirements of the particular plant which is being grown within the plant growth delivery system 100.

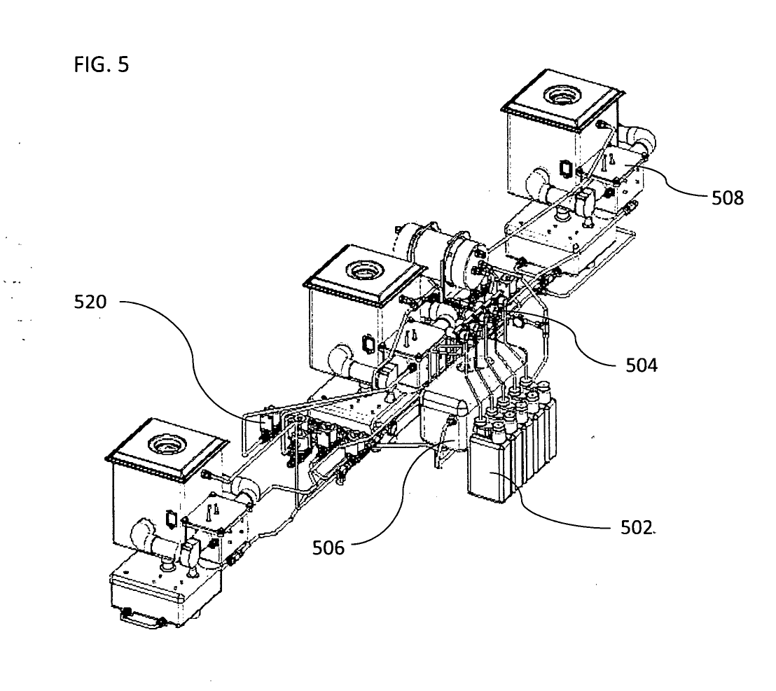

Referring to FIG. 3 in conjunction with FIGS. 3A, 3B and 3C as well as FIG. 4, there is shown an illustrative embodiment of the plant growth delivery system 100 in conjunction with its related cooling system 200 and evaporation system 300. As is best illustrated in FIG. 3A, and evaporate or glycol cooler 202 is employed beneath the plant growth delivery system. A variable speed fan 204 provides the airflow through the plant growth delivery system 100. The variable speed fan 204 is capable of providing multiple air flows through air supply tubes 206 which are advantageously deployed within each of the units of the plant growth delivery system 100.

The cooling system 200 air supply which is furnished to the plants is further enhanced by filtering the air through a HEPA filter (not shown) advantageously situated at HEPA filter port 208. The cooling system 200 air supply is provided into each of the one or more units comprising the plant growth delivery system 100 and is returned via bottom air return ducts 210. The cooling system 200 is further provided with an air supply register 212 which maybe deployed in connection with each of the one or more units comprising the plant growth delivery system 100.

The plant growth delivery system 100 is advantageously provided with rear mounted doors 214 each of which has disposed thereon a plurality of light emitting diodes 402. It will be appreciated that the rear mounted doors 214 maybe removably disposed in order to permit access to the plants and, the front mounted protective doors 104 make similarly be provided with a plurality of light emitting diodes 402 in order to provide a full surround of lights to the plants within the growth delivery system 100. Referring still to FIG. 3A combo there is also shown a series of carbon filter housings 216 disposed at the upper level of each of the units within the plant growth delivery system 100 to provide additional particulate matter and ambient odor removal.

Referring again to FIG. 3B, the air-conditioning condensing unit 108 having condenser fans 110 is connected to an air-conditioning compressor unit 218 which serves to provide constant temperature cool air at the temperature determined by the operator to be optimal for the particular plant and the particular phase of growth for that plant within the plant growth delivery system 100. As will be discussed at a later point in this specification, each of these units and others associated with the plant growth delivery system 100 may be controlled both proximately and remotely by the operator and are further controlled through sensors that are advantageously employed to determine such variables as carbon dioxide level, nutrient flow, humidity, and other applicable parameters to ensure maximum growth and viability of the plan at each stage of its growth cycle.

Referring to FIG. 3C, the evaporator system 300 is comprised of that evaporator glycol cooler 302 that is functionally connected to a glycol pump 304 which distributes the glycol through a series of freon line 306 through each of the units of the plant growth delivery system 100. A variable speed fan 308 is juxtaposed above a HEPA filter port 310 which sits above the bottom air return duct 312. In operation, the air is circulated through one or more air supply tubes 314 and out adjustable directional air vents 316 within each of the units that form a part of the plant growth delivery system 100.

Referring to FIG. 5, there is shown exemplary plumbing structure 500 for providing the nutrients, mist and other deliverables to the plants as well as obtaining data from plants and environment in order to provide control functions. A series of nutrient bottles 502 are disposed in connection with the plumbing structure 500, each of which provides one or more designated nutrients. Each of the nutrient bottles 502 maybe individually regulated or regulated in connection with other nutrient bottles 502 in order to supply optimal nutrients to the plants within the plant growth delivery system 100. Each of the nutrient bottles 502 is connected to a peristaltic pump 504. A main water tank reservoir 506 is integrally connected to and AeroVapor nutrient and H2O delivery unit 508 which mixes and delivers the combination of water and nutrients to the plants within the plant growth delivery system 100.

As will be further explained hereinafter the AeroVapor nutrient and H2O delivery unit 508 is controlled through the further part of the invention via a series of control and feedback loops and related optimization sensors that create an ongoing and continuously updated set of parameters in order to provide the optimal nutrients and water combination to the plants during each phase of their growth cycle.

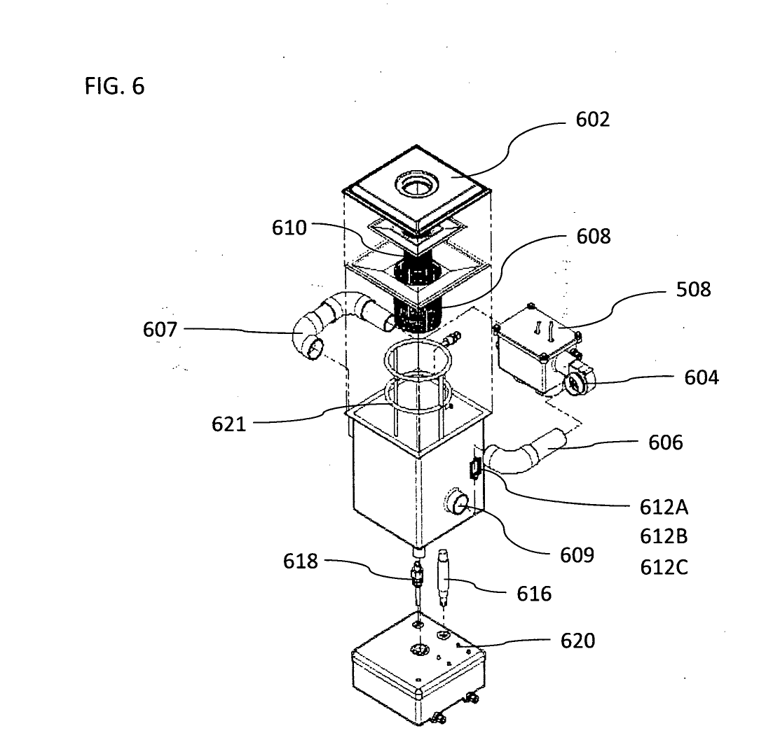

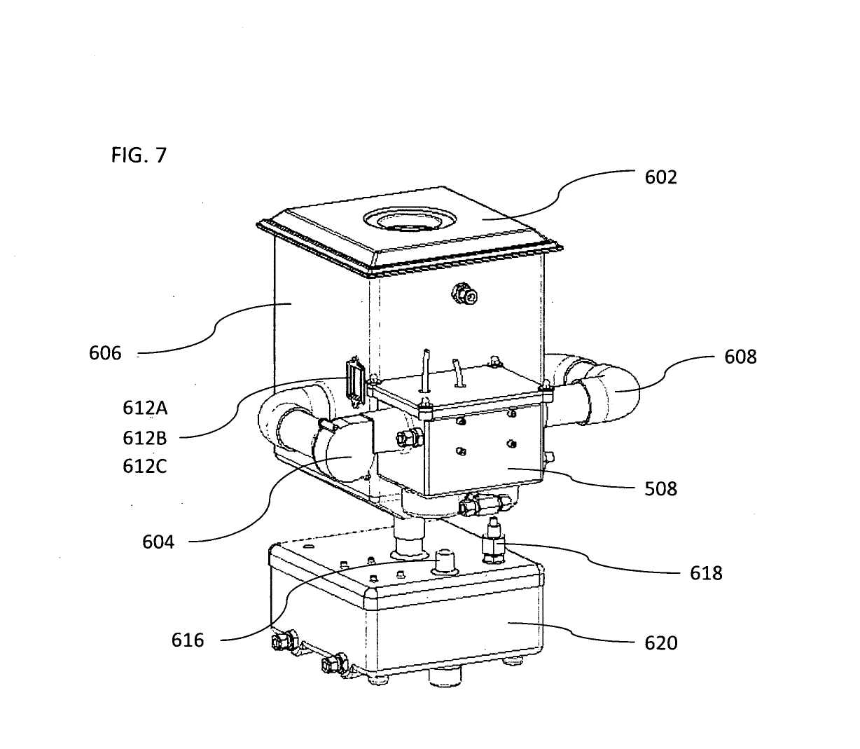

Referring to FIG. 5 in conjunction with FIG. 6 and FIG. 7, there is shown an exploded view of a root box assembly 600 which has as a part thereof the AeroVapor nutrient and H2O delivery unit 508. The root structure of a plant (not shown) is placed within the root box assembly 600 such that the roots are generally contained by the root box assembly 600 and are below the level of an airtight root box chamber cover 602. The AeroVapor nutrient and H2O delivery unit 508 is connected through a blower fan assembly 604 to an inflow tube 606 that is integrally connected to the lower portion of the root box assembly 600, below the level of the root box chamber cover 602.

Root baskets are deployed within the root box assembly below the level of the root box chamber cover 602. By way of example, there is shown a large root basket 608 and a small root basket 610 deployed within the root box assembly 600 below the level of the root box chamber cover 602. The inflow tube 606 opening 607 into the root box assembly 600 is advantageously disposed so that the nutrients and mist contact the roots of the plant substantially immediately upon entry into the root box assembly 600 and are disbursed throughout the root structure both by being blown in through the inflow tube 606 and being drawn through by means of an outflow tube 607 that is dispose on the opposite side from the inflow tube 606 at opening 609 and is functionally connected thereto, thus creating a controlled air flow current through the root structure.

A series of sensors are deployed in connection with the root box assembly 600 and may be disposed along its various side and bottom. Advantageously, oxygen 610, humidity 612 and air temperature 614 sensors are shown on a lateral wall of the root box assembly 600, while a pH sensor 616 and an environment control sensor 618 are connected a drain tank 620 that is disposed below the root box assembly 600 and into which falls the unabsorbed water and nutrients. The various above named sensors are only illustrative of the variety of sensors that may be deployed in connection with the root box assembly 600 and with the scope and breath of the invention. It has been found that deploying the sensors in the manner set forth above provides advantages in controlling the overall environment and provided truer data for such control than if the sensors are deployed elsewhere in the root box assembly 600.

The root box assembly 600 is also provided with a double watering ring assembly 621 that may provide water at various levels of the roots that are contained within the large root basket 608 or the small root basket 610. By providing both water and misting, as will be explained next, the roots receive the optimum water and nutrient mix which can be altered on a just-in-time basis predicated upon the information and data provided by each of the sensors and the underlying growth modeling that has been recorded and determined from prior growth cycles for the same species of plant or for other species with similar growth patterns.

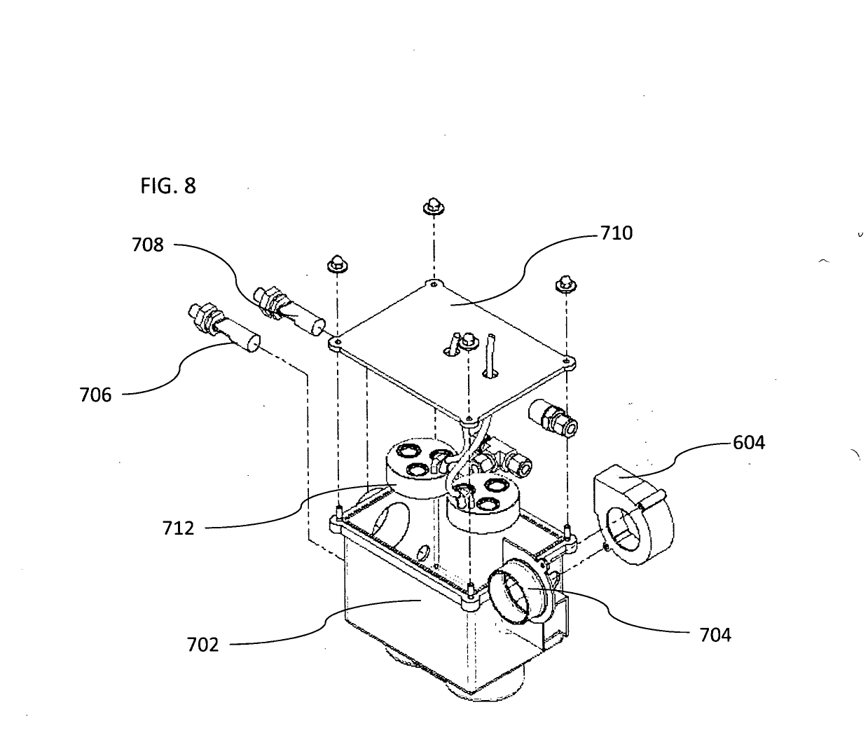

Referring to FIG. 8, there is shown an exploded view of the AeroVapor nutrient and H2O delivery unit 508. The operational elements of the AeroVapor nutrient and H2O delivery unit 508 are housed within a water containment unit 702 into which water and nutrients are placed in a controlled fashion through the operation of one or more of a series of water control solenoids 520 that operate in connection with the plumbing structure 500. The blower fan assembly 604 is shown in exploded form and in proximity to blower fan pipe attachment port 704 that mates to the inflow tube 606 that is integrally connected to the lower portion of the root box assembly 600, below the level of the root box chamber cover 602.

The water level in the containment unit 702 is monitored by an upper level water sensor 706 and a lower level water sensor 708 that cause the water level to be maintained within certain boundaries and ensure constant hydration of the roots in an optimal manner. The containment unit 702 has a water tight top 710 such that the water is capable of being fully controlled by elimination of evaporation, thus permitting the unit to provide substantially exact information as to water uptake as a function of the water sent into the system.

One or more ultrasonic piezo misting units 712 are deployed within each containment unit 702 to create the mist that is picked up in the airflow of the blower fan assembly 604 and distributed to the roots of the plant within the AeroVapor nutrient and H2O delivery unit 508.

In general, the plant growth delivery system 100 may be characterized as a multi-unit grow chamber for flowering plants in which there are controls for temperature, light, humidity, watering, nutrients, CO2, O2 and the capacity for misting roots for eliciting plant stress responses and to deliver peroxide for root health. The plant growth delivery system 100 may also have the capacity for fogging of the roots in such circumstances as may be desirable or needed for controlled stressing of the plants. It has been found that, among other plant species, the plant growth delivery system 100 is advantageously used for the enhanced growth of medicinal plants including cannabis and that the system may be advantageously employed to provide the capacity to filter out and recover terpenes.

Referring once again to FIG. 1 and FIG. 3, there is shown an illustrative surround of LED lights in each of the units of the plant growth delivery system 100 for flower development at all levels. The interior walls of the various protective wall covers 104 and 106 may have disposed thereon the light emitting diodes 400. They may also be reflective either by coating of the interior walls or by using a white reflective material that minimally absorbs the light emitted by the diodes 400.

The chlorophyll of the plants deployed within the plant growth delivery system 100 mainly absorb blue light with a relatively shorter wavelength and red light with a relatively longer wavelength. In order to enhance the illumination efficiency of light absorbed by the plants, the light emitted by the light emitting diodes 400 is, for example, blue, red or other colors which has a wavelength range within the spectrum absorbed by the chlorophyll of the plants. For examples, blue LED (light emitting diode) with the main peak of wavelength within 420 to 520 nm or red LED with the main peak of wavelength within 600 to 720 nm may be used for the light emitting diodes 400. In the light-emitting layers of the light emitting diodes 400 composed of metallic compound semiconductors, the metal is, for example, indium (In), or gallium (Ga), or germanium (Ge), or the composition of them; and the compound is, for example, nitrogen (N), or phosphor (P), or arsenic (As), or the composition of them.

For examples, when the light with suitable wavelengths emitted by the blue LED composed of nitrides such as indium gallium nitride (InGaN), or by the red LED composed of phosphides such as indium gallium phosphide (InGaP) or arsenides such as indium gallium arsenide (InGaAs), is absorbed by the chlorophyll of the plants, the percentage of illumination energy used by the plants can reach at least 10%. Therefore, the efficiency of photosynthesis carried out by the plants can be enhanced by use of the light emitting diodes 400 in the present invention.

The plants can obtain stable and adequate illumination from the light emitting diodes 400. These produce a full-spectrum light that is optimized for photosynthesis. By adding, exchanging or dimming specific diodes the light spectrum can also be adjusted to increase the production of flowers, fruit, essential oils or other desirable products. Thus the crop, i.e. the amount of the plants and the resultant crop that is produced, can also be increased. Furthermore, because of the light emitting diodes 400 with different optical wavelengths on the interior walls of the chamber are capable of being staged to provide different aggregate light during different parts of the growing cycle, users can deliberately facilitate the growth rate of either leaves or fruits of the plants in order to increase the crop of the plants.

Continuing to refer to FIG. 1 and FIG. 3, it is a further aspect of a preferred embodiment of the invention to employ programmed illumination cycles that used phytochrome modulation to induce flowering of Cannabis plants at light periods of less than 12 hours per/day. By using such phytochrome modulation, the Cannabis plant is capable of growing more rapidly and producing a harvestable crop more quickly, and thereby reducing the length of the cultivation cycle. Phytochrome is a photoreceptor that changes between active and inactive forms in the darkness or in response to exposure to far red-wavelength light and in particular narrow-band red LED lights. The benefit is that plants could be grown at longer daylight hours and still bloom. The configuration of the light-emitting diodes on both around and above the plant increases illumination of the lower parts of the plant that otherwise would be shaded by the upper leaves. This enhances overall flower production, as well as fruit development and ripening.

In another aspect of a preferred embodiment of the invention, oxygen from the atmospheric environment, the upper (shoot-) compartment, or from a supply may be transferred into the root box assembly 600, which increases root health and nutrient uptake. Oxygen that is produced in the photosynthesis of the plants is monitored in order to maintain an ideal and optimized relative percentage between the oxygen and carbon dioxide. If necessary to maintain the optimum balance, oxygen may be collected and discharged from the root box assembly 600 and either retained for subsequent equalization and optimization or discharged into the atmosphere. Carbon dioxide is absorbed from the air and converted to sugars during photosynthesis. Supplying the growing plants with supplemental carbon dioxide increases the rates of photosynthesis and growth. The enclosed environment allows for adjusting the carbon dioxide concentration in the shoot compartment effectively because only a relatively small volume has to be delivered. Furthermore, temporarily increasing the carbon dioxide concentration can be used as a non-chemical pest control measure.

As can be illustratively seen in FIG. 5 a preferred embodiment of the invention provides separate reservoirs for the individual nutrient solutions and solutions to adjust the pH up or down, all in accordance with the information received from the various monitors employed within the system. Thus, based upon oxygen level, temperature, humidity, carbon dioxide level, pH and other variables the necessary reservoirs are tapped to provide the nutrient solution and the appropriate pH for the plant at each phase of it's growth cycle. Each entry solution is prepared in the water tank and transferred to the plant via a nutrient mist that is directly applied to the roots by means of the AeroVapor nutrient and H2O delivery unit 508.

The temperature of the rhizosphere (roots) plays a very important role in plant growth because it is associated with the radical metabolism and assimilation of nutrients. In evolution, various plant species have adapted to different environments, cold or hot in respect of temperature. Consequently, the optimal growth temperature of the rhizosphere differs greatly among plant species, and even between cultivars of the same plant species. The regulation and control therefore of the rhizosphere temperature for the growing and harvesting of a crop is an important and critical aspect of the present invention.

A major advantage of the present invention is the automatic regulation and control of the temperature in the root zone, which is achieved by adjusting the temperature of the nutrient solution that is administered to the roots. Thus, the optimal temperature for each phase of the grow cycle can be maintained regardless of the temperature outside the device. The system has the ability to regulate the temperature of the supplied nutrient solution separately for the plant being grown and the crop which it is expected to bear.

Similarly, the temperature and humidity surrounding the crop bearing portion of the plant is important to the optimal growth and crop production. If humidity is too high, the crop may rot, while if it is too low it may dry out or not reach maximum development. Once a crop is stunted because of inclement surroundings, it may often never recover or reach its optimum potential. As will be set forth hereinafter, it is yet another aspect of a preferred embodiment of the invention to provide constant monitoring and adjustment of the multiple variables that will enhance and optimize a plant's productivity while also providing data to determine the best conditions for future maximum yield. It is a part of the invention to provide a learning model system for control of the plant growth delivery system 100 that teaches itself based upon past data derived from within the plant growth delivery system 100, current crop data as sensed by the plurality of sensors and crop data derived from outside of the plant growth delivery system 100 including environmental and natural growth data.

The present invention provides for an automatic root irrigation system providing the nutrient solution by pumps, transport pipes and misting under pressure (high or low) directly to the root inside root containers. The system is advantageously provided with automatic setting of time and frequency of mist provision based upon stored data and currently sensed data. The nutrient solutions for the plant growth delivery system 100 are both a closed circuit supply system, recirculating the nutrient solution that is not absorbed by the plants from the growing baskets back to the drain tanks where the resultant concentrations and nutrient values may be determined, as well as an open circuit system to replenish and correct nutrient values prior to delivery of the nutrients to the roots.

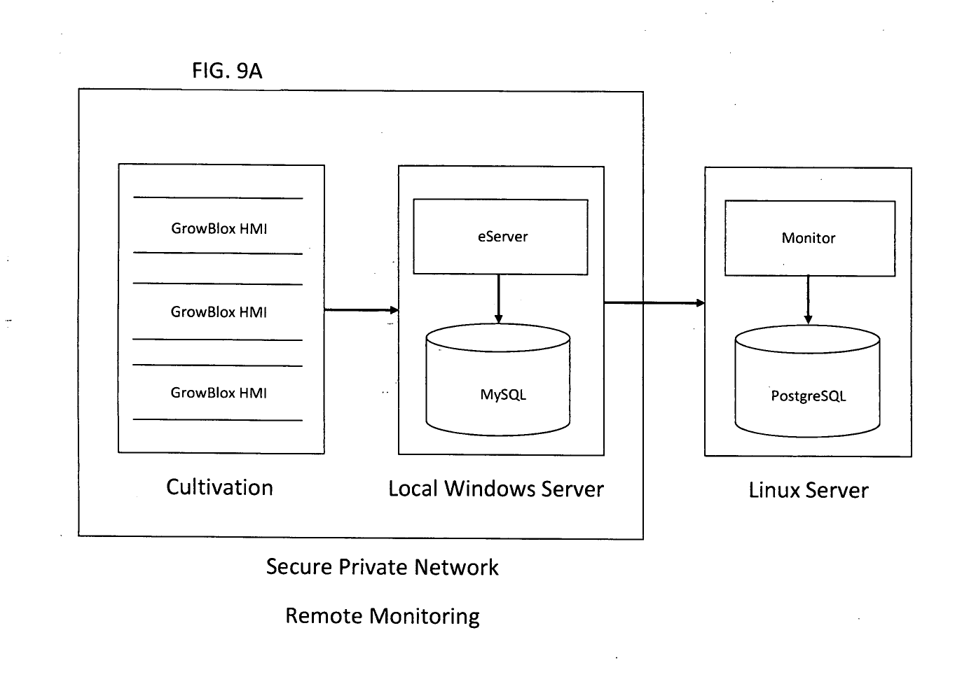

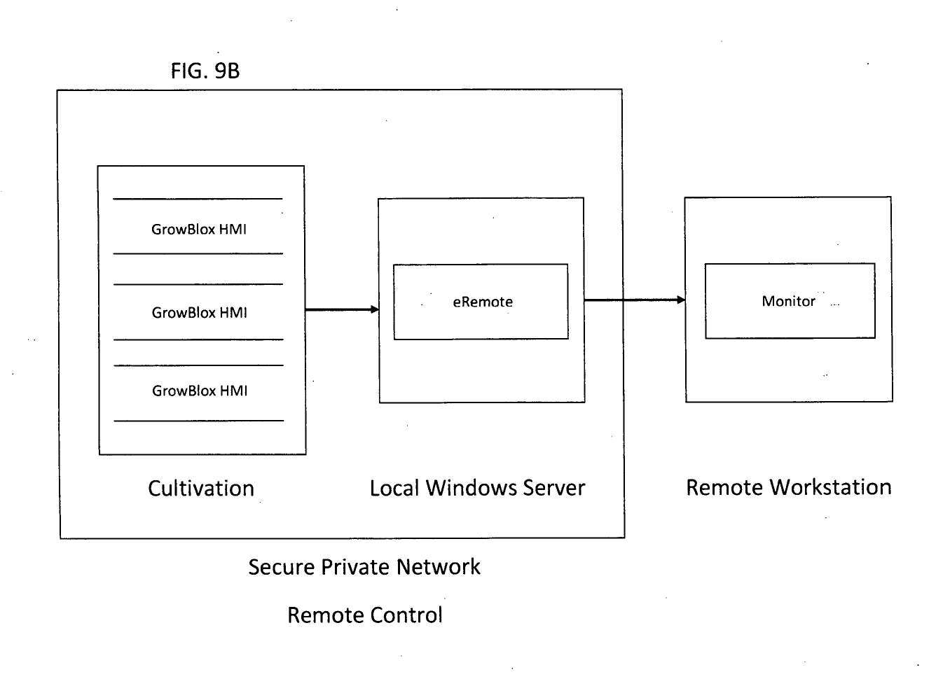

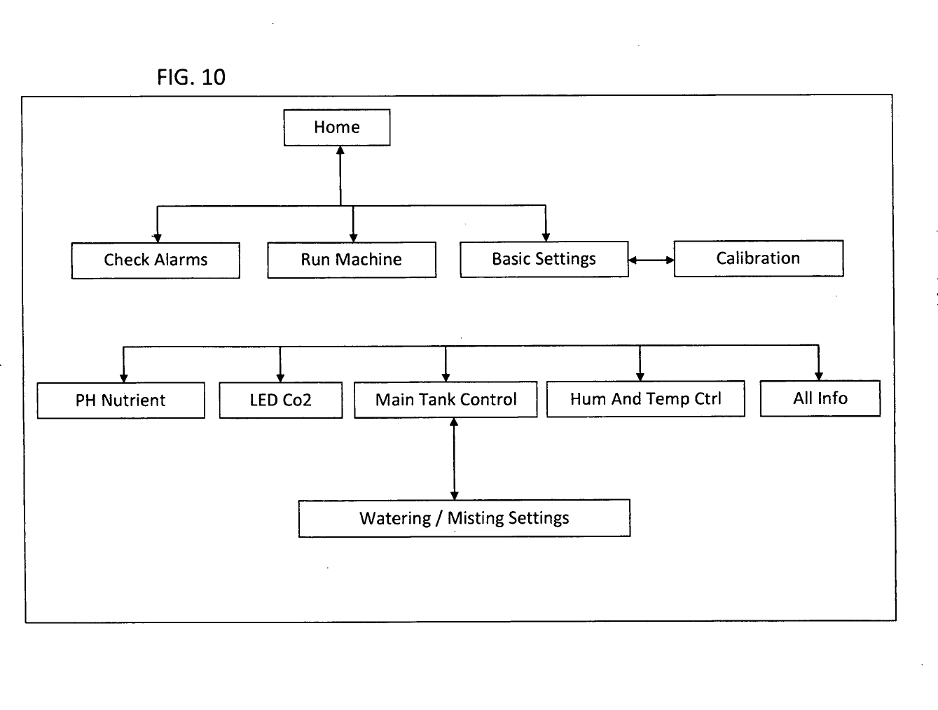

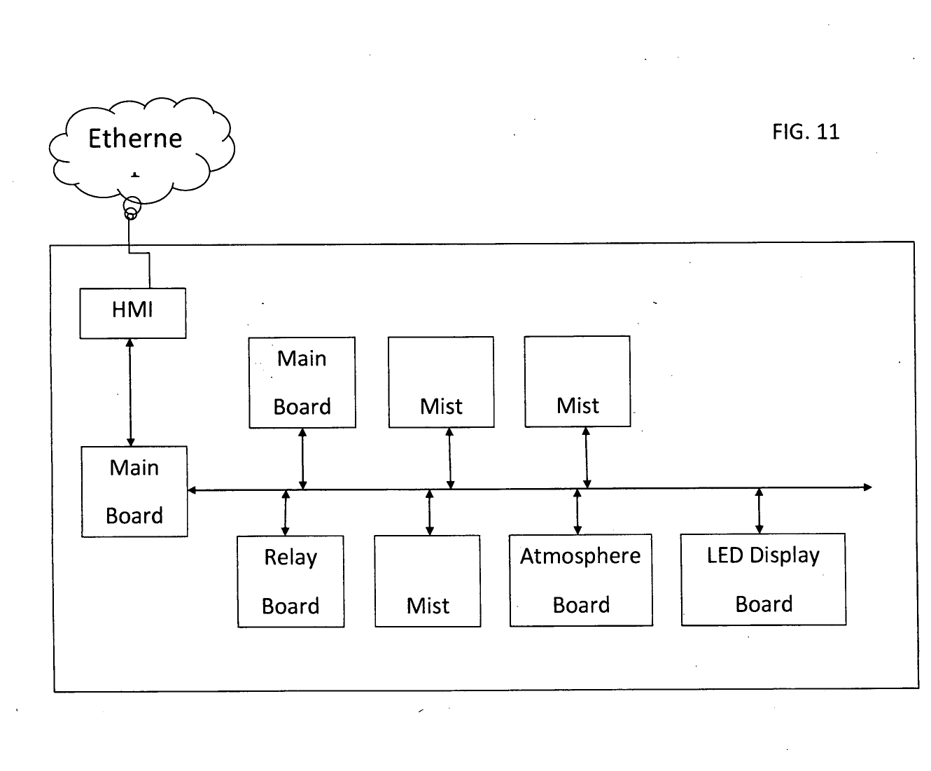

Referring to FIGS. 9A and 9B, in conjunction with FIGS. 10 and 11, there is illustratively shown a flow chart for a central automatic digital control system that may be operated by computer to provide monitoring and control of all of the individual parts of the system, and permit remote, on-line control.

The functional elements of FIG. 11 are:

| PCB board | number | Function |
|---|---|---|
| Main board | 1 | Communicate with slave boards, and control all |
| | | the components to set the GrowBlox run as |
| | | schedule. |
| Relay board | 1 | With 32 relays control most of the components in |
| | | the system |
| Fog Tank | 3 | Get root box hum/temp/0₂ data |
| | | Get fog tank water level |
| | | Get drain tank water level |
| | | Control piezo mister, mister fan |
| | | Control 0₂ Solenoid |
| Main tank | 1 | Get water level of main tank |
| | | Get Temperature, pH, EC value of main tank |
| | | water. |
| | | Get flow meter output from water in flow meter |
| | | feeding flow meter and glycol cycle flow meter |
| Atmosphere | 1 | Get air temp and humidity |
| block | | Get C02 concentration |
| LED Display | 1 | Display important data in the LED dot array |
| Board | | board. |

The Main Tank Block electronic are designed to perform the following and transmit the below data to control the system:
a. Collect the water level data through 3 level switches;
b. Get the water temperature through H2O Temperature probe.
c. Get the water pH value through pH probe.
d. Get EC value through EC probe.
e. Get how much water has been put into the machine through the water-in flow meter.
f. Get how much water has been fed to plants the machine through the feeding flow meter.
g. Feedback whether the glycol cycling is on by the glycol flow meter.
h. The water level limit switch will be on if the top water level sensor is on.

The Misting Tank Block electronic are designed to perform the following and transmit the below data to control the drain tank and misting tank.
a. Get the water level of the drain tank
b. Get the water level of the misting tank
c. Get the pH value of drain tank.
d. Get the EC value of drain tank.
e. Water level limit switch will be on when the high level sensor of the drain tank is on.
f. Get humidity and temperature of the root box
g. Get the O2 concentration of the root box
h. Control the piezo misters, fog fan and O2 solenoid.

The Atmosphere Control Board will collect the CO2 concentration, air temperature and humidity, then send that data to the center board through 485 bus. The center board will control the CO2 solenoid and AC system to maintain the CO2 concentration and air temperature at a level that will serve to optimize the plant growth within the plant growth delivery system 100.

Referring again to FIG. 6, there is shown the pH sensor and EC sensor within the drain tank to measure and provide data as to what the nutrient levels are within the tank. The use of a pH sensor and EC sensor are exemplary and other sensors may be employed to provide specific data based upon on individual nutrient concentrations, the plant that is being grown, the stage of the growth cycle and the determination by the operator as to what they deem to be optimal. Thus, this can be a way of providing alternate chemical levels to study the effects on various plants at different stages of the growth cycle.

Because there are sensors in the drain tank, the operator has the measurements and data from both the mixing tank as to what was provided to the plants and the drain tank. This information can be employed to compare the relative uptake of nutrients and moisture and the resultant calculation can be provided back to provide both an adjustment in the next feeding cycle as well as the compilation of a library of data to permit future adjustments both for the particular plant and subsequent plants. This provides the operator with the ability to control the feeding/nutrients and record how plant roots absorb their requirements. Such data provide indirect testing to see what actually is consumed by a plant.

The operator can use the known compositions of the starting nutrient mixtures and added amounts of water to calculate consumption based on levels sampled from the drain tank. The system can also, based upon other sensors, determine how much is suspended as mist, how much water is lost to evaporation, etc. and thus obtain, over time and on a real time basis, the comparative data to help determine actual grow programs/schedules that produce the best grow rates and yields.

In operation, the following exemplary parameters may be employed for the growing of Cannabis. It will be appreciated that these are only provided as indicia for the above species of plant and that the system may be advantageously employed with many other species of plants, both for growth, harvesting or for plant studies and experimentation. Thus, the parameters may be altered to provide optimal growth, harvesting or for plant studies and experimentation based upon the particular species within the system.

Exemplary Cannabis Parameters:

### Air Temperature

Shoot Zone: 20-25° C. (68-77° F.)
Root zone: 18-22° C. (64-72° F.)

### Humidity—Ambient and Root Box

Shoot zone: app. 60% during vegetative growth and 50% during flowering
   Root zone: will be close to 100%, depending on the spray cycle. Monitor to avoid drying.
   pH—Main Tank, Drain Box
pH control: main tank only (pH 5.8+/−0.1)
pH measurement: drain tank for feedback and main tank for adjustment

### Lights—Spectrum, Spread and Intensity

Spectrum: full-spectrum LED with additional red as in Spectrum King newest version:
   Additional capacity to illuminate the plants temporarily with narrow-spectrum far red light of peak wavelength 730 nm but less than 10% of <700 nm for phytochrome conversion. Light intensity of 20-100 μmol×m⁻²×s⁻¹ PAR is sufficient. Can be achieved with app. 10 GU10 lights in one preferred embodiment of the plant growth delivery system 100.

### Intensity/Spread

A plant growth delivery system 100 with GU-10 lights delivers a good distribution of the light intensity to all three compartments. Test at the three different levels in the box at 85% intensity of the 5 Watt lights:

| | distance from light | | | | | |
|---|---|---|---|---|---|---|
| | 6″ | | 12″ | | 18″ | |
| | direction of sensor | | | | | |
| | at light | indirect | at light | indirect | at light | indirect |
| Bottom | 95 | 266 | 179 | 183 | 150 | 144 |
| Mid | 352 | 249 | 192 | 198 | 210 | 208 |
| Top | 278 | 307 | 180 | 186 | 167 | 165 |

Additionally, without the top lights installed and chips of 5 W instead of 10 W as specified and at 85% intensity (to avoid over-heating) the reflection and interference of the individual light sources provide a much more even distribution of the light throughout the plant growth delivery system 100 as can be achieved with top lights.

### Measure: Main Tank and Drain Tank

Control: EC is controlled through nutrient feed. The measurements are used to adjust the nutrients and to monitor uptake in the root zone.

Misting and Fogging
Regular fogging (5 μM droplets) is a likely cause of lower stem rot and by itself not sufficient to deliver all nutrients. Intermittent spraying or misting of the roots with a coarser mist (20-50 μM droplets) has shown much better results. The fog is not essential for growing the plant.
Fog is used for “shocking” roots in order to elicit biochemical responses and to adjust humidity in the root zone. Fast, temporary effects require to deliver the solution from a different tank than the main tank or drain tank.
Fog is also used to increase humidity in the root zone to prevent drying.

Watering the Roots
water and nutrient delivery through fine mist (app. 50 μM droplets), applied to the upper level of the root box
mist should be distributed evenly in the root box
a particle filter may be advantageously employed to protect the nozzles
alternatively, a temporarily increase in pressure may be employed for nozzle cleaning

O2—Range Determination
Root box only. The range for an ideal atmospheric O2 in the root zone for growth may be determined based upon the plants to be grown. Ideally, it should not drop below 20%, which is ambient but higher O2 might be beneficial. O2 content in the water can be adjusted by aeration and H₂O₂ addition, among other means.
In order to reduce the risk of depleting oxygen in the root zone, it is recommended that the O2 is monitored and supplemented if necessary. Also, the higher CO2 level in the shoot zone might affect the root zone atmosphere.
It is also recommended that the main tank be aerated.

CO2—Range in the Ambient, Root Box
CO2 in the shoot zone: 400 (ambient) to 8,000 ppm (for pest control), maintained at 1000-2500 ppm throughout grow during the daytime and 400 ppm during the night.
Use of pest control protocol (up to 8,000 ppm CO2) must be limited to necessity, as possibility of necrosis in the plants leaves from over exposure to CO2.
Root zone: no additional CO2 in the root zone

### Frequency of Feeding/Misting and Fogging

Feeding: Typical intervals are 30 sec to 3 min spray with 60-240 min off, depending on the plant size and stage of development. Maximum interval between sprays/misting must be achieved so as to not over feed or over saturate the root zone.
Fogging: The fog would normally be off and only come on for periods of up to 10 minutes with off cycles to be determined by the effect the treatment has on the plant and the necessity to not over-water the plant.

### Water Quality Requirements

Initially use R/O water to ensure consistency of the nutrient solutions, avoid buildup of heavy metals, prevent scaling and establish baselines for growth
Subsequent to the establishment of baselines and determination of variations based upon nutrient/water concentrations and other mix variables:
   Obtain information about local water source from water department, including seasonal variations and establish critical parameters: hardness (Ca and total), alkalinity, pH, sodium, chloride, chlorine or chloramines, heavy metals
   verify with regular in-house and contract laboratory testing
   provide minimum filtration requirement: particles, activated carbon
   provide optional electronic wave pre-treatment for scale prevention and biofilm reduction

### Leaf Movement

there must be adequate air flow, which may be determined by evaluation in non-growth chamber environments of the leaf movement and natural air flow requirement. These may then be employed to determine airflow within the chamber that is required to simulate the natural flow requirements. In the plant growth delivery system 100 minimum air flow is determined by the cooling requirements.
Directional air flow should be provided to prevent mildew in the denser zones to prevent humidity buildup.
The A/C, airflow, and dehumidification systems should be independent. To properly cool the operator should not be over circulating the plants which will reduce yields (too much wind causes the leaves to interfere (rub) against developing blooms and stunt bloom development).
During the night time cycle, when A/C units are not necessary, the humidity will be kept within parameter (<45% RH) with additional dehumidification.

### Day and Night Time Frames

Lights on 12-24 h. Cycles depend on the developmental stage of the plants.

Algorithms may be executed by a system-associated processor to optimize growth/energy consumption, track O2 movement, deliver/reclaim water, handle all aspects of nutrition, utilize sensor data to control a system function, empirically determine a control sequence such as with a machine learning system, provide simulation-based control, determine and execute a nutrient schedule, such as one based on a condition such as calcium deficiency or one based on a profile.

Data from the system may be used in predictive analytics (e.g. Growth prediction), Growth cycle analysis, Event analysis (failure modes, Pathogen monitoring), performing a historical analysis of all controlled variables at rack level for entire growth cycle, perform growth modeling and statistics, generate computer simulation models (tool kit), and the like.

The methods and systems described herein may be deployed in part or in whole through a machine that executes computer software, program codes, and/or instructions on a processor. The processor may be part of a server, cloud server, client, network infrastructure, mobile computing platform, stationary computing platform, or other computing platform. A processor may be any kind of computational or processing device capable of executing program instructions, codes, binary instructions and the like. The processor may be or include a signal processor, digital processor, embedded processor, microprocessor or any variant such as a co-processor (math co-processor, graphic co-processor, communication co-processor and the like) and the like that may directly or indirectly facilitate execution of program code or program instructions stored thereon. In addition, the processor may enable execution of multiple programs, threads, and codes. The threads may be executed simultaneously to enhance the performance of the processor and to facilitate simultaneous operations of the application. By way of implementation, methods, program codes, program instructions and the like described herein may be implemented in one or more thread. The thread may spawn other threads that may have assigned priorities associated with them; the processor may execute these threads based on priority or any other order based on instructions provided in the program code. The processor may include memory that stores methods, codes, instructions and programs as described herein and elsewhere. The processor may access a storage medium through an interface that may store methods, codes, and instructions as described herein and elsewhere. The storage medium associated with the processor for storing methods, programs, codes, program instructions or other type of instructions capable of being executed by the computing or processing device may include but may not be limited to one or more of a CD-ROM, DVD, memory, hard disk, flash drive, RAM, ROM, cache and the like.

A processor may include one or more cores that may enhance speed and performance of a multiprocessor. In embodiments, the process may be a dual core processor, quad core processors, other chip-level multiprocessor and the like that combine two or more independent cores.

The methods and systems described herein may be deployed in part or in whole through a machine that executes computer software on a server, client, firewall, gateway, hub, router, or other such computer and/or networking hardware. The software program may be associated with a server that may include a file server, print server, domain server, internet server, intranet server and other variants such as secondary server, host server, distributed server and the like. The server may include one or more of memories, processors, computer readable media, storage media, ports (physical and virtual), communication devices, and interfaces capable of accessing other servers, clients, machines, and devices through a wired or a wireless medium, and the like. The methods, programs or codes as described herein and elsewhere may be executed by the server. In addition, other devices required for execution of methods as described in this application may be considered as a part of the infrastructure associated with the server.

The server may provide an interface to other devices including, without limitation, clients, other servers, printers, database servers, print servers, file servers, communication servers, distributed servers, social networks, and the like. Additionally, this coupling and/or connection may facilitate remote execution of program across the network. The networking of some or all of these devices may facilitate parallel processing of a program or method at one or more location without deviating from the scope of the disclosure. In addition, any of the devices attached to the server through an interface may include at least one storage medium capable of storing methods, programs, code and/or instructions. A central repository may provide program instructions to be executed on different devices. In this implementation, the remote repository may act as a storage medium for program code, instructions, and programs.

The software program may be associated with a client that may include a file client, print client, domain client, internet client, intranet client and other variants such as secondary client, host client, distributed client and the like. The client may include one or more of memories, processors, computer readable media, storage media, ports (physical and virtual), communication devices, and interfaces capable of accessing other clients, servers, machines, and devices through a wired or a wireless medium, and the like. The methods, programs or codes as described herein and elsewhere may be executed by the client. In addition, other devices required for execution of methods as described in this application may be considered as a part of the infrastructure associated with the client.

The client may provide an interface to other devices including, without limitation, servers, cloud servers, other clients, printers, database servers, print servers, file servers, communication servers, distributed servers and the like. Additionally, this coupling and/or connection may facilitate remote execution of program across the network. The networking of some or all of these devices may facilitate parallel processing of a program or method at one or more location without deviating from the scope of the disclosure. In addition, any of the devices attached to the client through an interface may include at least one storage medium capable of storing methods, programs, applications, code and/or instructions. A central repository may provide program instructions to be executed on different devices. In this implementation, the remote repository may act as a storage medium for program code, instructions, and programs.

The methods and systems described herein may be deployed in part or in whole through network infrastructures. The network infrastructure may include elements such as computing devices, servers, cloud servers, routers, hubs, firewalls, clients, personal computers, communication devices, routing devices and other active and passive devices, modules and/or components as known in the art. The computing and/or non-computing device(s) associated with the network infrastructure may include, apart from other components, a storage medium such as flash memory, buffer, stack, RAM, ROM and the like. The processes, methods, program codes, instructions described herein and elsewhere may be executed by one or more of the network infrastructural elements.

The methods, program codes, and instructions described herein and elsewhere may be implemented on a cellular network having multiple cells. The cellular network may either be frequency division multiple access (FDMA) network or code division multiple access (CDMA) network. The cellular network may include mobile devices, cell sites, base stations, repeaters, antennas, towers, and the like. The cell network may be a GSM, GPRS, 3G, EVDO, mesh, or other networks types.

The methods, programs codes, and instructions described herein and elsewhere may be implemented on or through mobile devices. The mobile devices may include navigation devices, cell phones, mobile phones, mobile personal digital assistants, laptops, palmtops, netbooks, pagers, electronic books readers, music players and the like. These devices may include, apart from other components, a storage medium such as a flash memory, buffer, RAM, ROM and one or more computing devices. The computing devices associated with mobile devices may be enabled to execute program codes, methods, and instructions stored thereon. Alternatively, the mobile devices may be configured to execute instructions in collaboration with other devices. The mobile devices may communicate with base stations interfaced with servers and configured to execute program codes. The mobile devices may communicate on a peer to peer network, mesh network, or other communications network. The program code may be stored on the storage medium associated with the server and executed by a computing device embedded within the server. The base station may include a computing device and a storage medium. The storage device may store program codes and instructions executed by the computing devices associated with the base station.

The computer software, program codes, and/or instructions may be stored and/or accessed on machine readable media that may include: computer components, devices, and recording media that retain digital data used for computing for some interval of time; semiconductor storage known as random access memory (RAM); mass storage typically for more permanent storage, such as optical discs, forms of magnetic storage like hard disks, tapes, drums, cards and other types; processor registers, cache memory, volatile memory, non-volatile memory; optical storage such as CD, DVD; removable media such as flash memory (e.g. USB sticks or keys), floppy disks, magnetic tape, paper tape, punch cards, standalone RAM disks, Zip drives, removable mass storage, off-line, and the like; other computer memory such as dynamic memory, static memory, read/write storage, mutable storage, read only, random access, sequential access, location addressable, file addressable, content addressable, network attached storage, storage area network, bar codes, magnetic ink, and the like.

The methods and systems described herein may transform physical and/or or intangible items from one state to another. The methods and systems described herein may also transform data representing physical and/or intangible items from one state to another.

The elements described and depicted herein, including in flow charts and block diagrams throughout the figures, imply logical boundaries between the elements. However, according to software or hardware engineering practices, the depicted elements and the functions thereof may be implemented on machines through computer executable media having a processor capable of executing program instructions stored thereon as a monolithic software structure, as standalone software modules, or as modules that employ external routines, code, services, and so forth, or any combination of these, and all such implementations may be within the scope of the present disclosure. Examples of such machines may include, but may not be limited to, personal digital assistants, laptops, personal computers, mobile phones, other handheld computing devices, medical equipment, wired or wireless communication devices, transducers, chips, calculators, satellites, tablet PCs, electronic books, gadgets, electronic devices, devices having artificial intelligence, computing devices, networking equipment, servers, routers and the like. Furthermore, the elements depicted in the flow chart and block diagrams or any other logical component may be implemented on a machine capable of executing program instructions. Thus, while the foregoing drawings and descriptions set forth functional aspects of the disclosed systems, no particular arrangement of software for implementing these functional aspects should be inferred from these descriptions unless explicitly stated or otherwise clear from the context. Similarly, it will be appreciated that the various steps identified and described above may be varied, and that the order of steps may be adapted to particular applications of the techniques disclosed herein. All such variations and modifications are intended to fall within the scope of this disclosure. As such, the depiction and/or description of an order for various steps should not be understood to require a particular order of execution for those steps, unless required by a particular application, or explicitly stated or otherwise clear from the context.

The methods and/or processes described above, and steps thereof, may be realized in hardware, software or any combination of hardware and software suitable for a particular application. The hardware may include a general purpose computer and/or dedicated computing device or specific computing device or particular aspect or component of a specific computing device. The processes may be realized in one or more microprocessors, microcontrollers, embedded microcontrollers, programmable digital signal processors or other programmable device, along with internal and/or external memory. The processes may also, or instead, be embodied in an application specific integrated circuit, a programmable gate array, programmable array logic, or any other device or combination of devices that may be configured to process electronic signals. It will further be appreciated that one or more of the processes may be realized as a computer executable code capable of being executed on a machine readable medium.

The computer executable code may be created using a structured programming language such as C, an object oriented programming language such as C++, or any other high-level or low-level programming language (including assembly languages, hardware description languages, and database programming languages and technologies) that may be stored, compiled or interpreted to run on one of the above devices, as well as heterogeneous combinations of processors, processor architectures, or combinations of different hardware and software, or any other machine capable of executing program instructions.

Thus, in one aspect, each method described above and combinations thereof may be embodied in computer executable code that, when executing on one or more computing devices, performs the steps thereof. In another aspect, the methods may be embodied in systems that perform the steps thereof, and may be distributed across devices in a number of ways, or all of the functionality may be integrated into a dedicated, standalone device or other hardware. In another aspect, the means for performing the steps associated with the processes described above may include any of the hardware and/or software described above. All such permutations and combinations are intended to fall within the scope of the present disclosure.

The above systems and methods have been described in the context of a plant growth delivery system 100. It is to be understood that these systems and methods apply equally to methods and systems which employ soil to grow plants. Many of these systems and methods may incorporate soil into the racks holding the plants and also result in the benefits described for the plant growth delivery system 100 systems and methods.

While the disclosure has been disclosed in connection with the preferred embodiments shown and described in detail, various modifications and improvements thereon will become readily apparent to those skilled in the art. Accordingly, the spirit and scope of the present disclosure is not to be limited by the foregoing examples, but is to be understood in the broadest sense allowable by law.

All documents referenced herein are hereby incorporated by reference.

What is claimed is:

1. A plant growth delivery system for optimizing, promoting and enhancing the rapid growth of a least one plant during one or more stages of its development cycle comprising:
a. a substantially closed container, having a root retention assembly therein, into which the plant is placed, with its roots in said root retention assembly;
b. a dispensing assembly containing at least one nutrient solution;
c. a misting assembly having a controllable interconnection to the dispensing assembly to provide a controlled amount of the nutrient solution into a controlled airflow;
d. a blower assembly in proximity to the misting assembly to create the controlled airflow from the misting assembly to the area of the root retention assembly;
e. at least one artificial growth inducing light source;
f. at least one nutrient sensor adapted to determine, either directly or indirectly, the nutrient uptake of the plant;
g. at least one environmental sensor adapted to determine, either directly or indirectly, atmospheric conditions within the substantially closed container;
h. at least one growth sensor system adapted to determine, either directly or indirectly, the growth of the plant;
i. a controller coupled to the artificial growth inducing light source and to the at least one growth sensor, environmental sensor and nutrient sensor adapted to: read information from the growth sensor to determine if growth has occurred; calculate the amount of nutrient to be delivered in the next feeding cycle; calculate the total number of on/off light cycles and a duration for each on/off cycle, and control the artificial growth inducing light source and alter the atmospheric conditions within the container to optimize the particular developmental cycle of growth desired.

2. A plant growth delivery system in accordance with claim 1, wherein the misting assembly further comprises a misting system.

3. A plant growth delivery system in accordance with claim 2 in which the plant is selected from a group consisting of plants from which may be derived medicinal extracts.

4. A plant growth delivery system in accordance with claim 3 in which the plant is selected from a group consisting of a species of Cannabis.

5. A plant growth delivery system in accordance with claim 2, wherein the misting system provides a nutrient and water solution in a mist form of between 30 μM and 80 μM droplets.

6. A plant growth delivery system in accordance with claim 2 in which the nutrient and water solution is monitored to determine whether the plant is uptaking sufficient water and nutrients for pre-determined optimal growth.

7. A plant growth delivery system in accordance with claim 2 in which the nutrient and water solution is provided on a “just-in-time” basis.

8. A plant growth delivery system in accordance with claim 2 in which the at least one environmental sensor is monitored to determine atmospheric conditions and said conditions are altered to provide conditions that are pre-determined for optimal growth.

9. A plant growth delivery system in accordance with claim 2 in which the artificial growth inducing light source is varied to provide phytochrome modulation.

10. A plant growth delivery system in accordance with claim 9 in which the artificial growth inducing light source causes phytochrome modulation by providing far red-wavelength light.

11. A plant growth delivery system in accordance with claim 10 in which said phytochrome modulation produces a shortened cultivation cycle.

12. A plant growth delivery system in accordance with claim 2 in which the plant is selected from a group consisting of plants which may be artificially optimized at one or more points in the growth cycle.

13. A plant growth delivery system in accordance with claim 1, wherein the monitoring and control may be performed either remotely from or proximate to the container.

14. A plant growth delivery system in accordance with claim 2 in which the artificial growth inducing light source is comprised of one or more LED.

15. A plant growth delivery system in accordance with claim 14 in which the LEDs are capable of providing light at fixed wavelengths and varying intensities in accordance with a user determined schedule.

16. A plant growth delivery system in accordance with claim 14 in which the LEDs are arranged in a pattern that illuminates the plant from both all sides and the top, thus increasing flower and fruit development on the lower parts of the plant.

17. A plant growth delivery system in accordance with claim 2 further comprising a system associated processor to execute an algorithm perform at least one of the following: (i) optimize growth/energy consumption; (ii) track O2 movement; (iii) deliver/reclaim water; (iv) handle all aspects of nutrition; (v) utilize sensor data to control a system function; (vi) iteratively determine a control sequence such as with a machine learning system; (vii) provide simulation-based control; or (viii) determine and execute a nutrient schedule, such as one based on a condition such as calcium deficiency or one based on a profile.

18. A plant growth delivery system in accordance with claim 2 further comprising a system associated processor to compile and analyze data from the system to generate predictive analytics, growth cycle analysis, event analysis, performing a historical analysis of all controlled variables at root and container level for an entire growth cycle, perform growth modeling and statistics, generate computer simulation models and provide optimization data for subsequent plant growth cycles.

19. A plant growth delivery system in accordance with claim 3 wherein the medicinal plants are produced in aseptic conditions.

20. A plant growth delivery system in accordance with claim 18 wherein the cultivation and processing protocols provide uniform medicinal extracts independent of the location of production, season or personnel.

21. A plant growth delivery system in accordance with claim 19 wherein the cultivation and processing further generate standardized propagation and cultivation conditions to provide uniform medicinal extracts independent of the location of production, season or personnel.

22. A plant growth delivery system in accordance with claim 3 wherein the medicinal plants are produced to provide plant extracts that are of reproducible chemical composition and purity.
